(19) United States
(12) Patent Application Publication
(10) Pub. No.: US 2023/0041352 A1
(43) Pub. Date: Feb. 9, 2023

(54) INTERCONNECT STRUCTURE AND ELECTRONIC DEVICE INCLUDING THE SAME

(71) Applicant: Samsung Electronics Co., Ltd., Suwon-si (KR)

(72) Inventors: Keunwook SHIN, Yongin-si (KR); Seunggeol NAM, Suwon-si (KR); Kyung-Eun BYUN, Seongnam-si (KR); Hyeonjin SHIN, Suwon-si (KR)

(73) Assignee: Samsung Electronics Co., Ltd., Suwon-si (KR)

(21) Appl. No.: 17/565,807

(22) Filed: Dec. 30, 2021

(30) Foreign Application Priority Data
Aug. 9, 2021 (KR) 10-2021-0104813

(51) Int. Cl. H01L 23/528; H01L 23/532

(52) U.S. Cl. CPC H01L 23/5283; H01L 23/53266; H01L 23/53238; H01L 23/53223; H01L 23/53252

(57) ABSTRACT

Provided are an interconnect structure and an electronic device including the interconnect structure. The interconnect structure may include a dielectric layer including a trench; a conductive line in the trench; and a first cap layer on an upper surface of the conductive line. The first cap layer may include a graphene-metal composite including graphene and a metal mixed with each other.

### CROSS-REFERENCE TO RELATED APPLICATION

This application is based on and claims priority under 35 U.S.C. §119 to Korean Patent Application No. 10-2021-0104813, filed on Aug. 9, 2021, in the Korean Intellectual Property Office, the disclosure of which is incorporated by reference herein in its entirety.

### BACKGROUND

### 1. Field

The present disclosure relates to interconnect structures and/or electronic devices including the interconnect structures.

### 2. Description of the Related Art

In recent years, the size of semiconductor devices has been gradually reduced to increase the degree of integration, and to this end, reducing the line width of copper wiring in interconnect structures may be required. However, a decrease in the line width of copper wiring may cause an increase in the current density of the copper wiring, which may cause an increase in the resistance of the copper wiring. In addition, the increase in the resistance of the copper wiring may cause electromigration of copper atoms, and thus, defects may occur in the copper wiring. Therefore, to lower the resistance of copper wiring and prevent electromigration of the copper atoms, a cap layer capable of improving the electromigration resistance of copper wiring may be required.

### SUMMARY

Provided are interconnect structures and/or electronic devices including the interconnect structures.

Additional aspects will be set forth in part in the description which follows and, in part, will be apparent from the description, or may be learned by practice of the presented embodiments of the disclosure.

According to an embodiment, an interconnect structure may include: a dielectric layer including a trench; a conductive line in the trench; and a first cap layer on an upper surface of the conductive line. The first cap layer may include a graphene-metal composite including graphene and a metal mixed with each other.

In some embodiments, the graphene-metal composite may include metal particles dispersed in the graphene.

In some embodiments, the graphene-metal composite may include graphene particles dispersed in the metal.

In some embodiments, the graphene-metal composite may have a carbon content profile in which a carbon content gradually decreases in a direction from the graphene to the metal.

In some embodiments, the graphene may include intrinsic graphene or nanocrystalline graphene.

In some embodiments, the metal may include at least one of Ru, Co, Ti, Ta, Al, Rh, Ir, and Pt.

In some embodiments, the graphene-metal composite may include the metal in an amount of about 1 at% to about 80 at%.

In some embodiments, the first cap layer may have a thickness of about 3 nm or less.

In some embodiments, the conductive line may include at least one of a metal element, a metal alloy, and a combination thereof. The conductive line may include at least one of Cu, Ru, Al, Co, W, Mo, Ti, Ta, Ni, Pt, Cr, Rh, Ir, Pd, and Os.

In some embodiments, the dielectric layer may include a dielectric material having a dielectric constant of about 3.6 or less.

In some embodiments, the interconnect structure may further include a second cap layer inside the trench on a lateral surface of the conductive line and a lower surface of the conductive line. The second cap layer may include the graphene-metal composite.

In some embodiments, the interconnect structure may further include a barrier layer on the conductive line inside the trench.

In some embodiments, the barrier layer may cover a lateral surface of the conductive line and a lower surface of the conductive line. The barrier layer may additionally cover the upper surface of the conductive line.

In some embodiments, the barrier layer may include a metal element, a metal alloy, a metal nitride, or graphene.

In some embodiments, the interconnect structure may further include a second cap layer on a lateral surface of the barrier layer and a lower surface of the barrier layer. The second cap layer may include the graphene-metal composite.

In some embodiments, the interconnect structure may further include a second cap layer on a lateral surface of the barrier layer and the second cap layer may include the graphene-metal composite.

In some embodiments, the interconnect structure may further include a second cap layer on a lower surface of the barrier layer and the second cap layer may include the graphene-metal composite.

According to an embodiment, an electronic device may include the interconnect structure.

According to an embodiment, an interconnect structure may include: a dielectric layer including a trench; a conductive line in the trench; and a cap layer on the dielectric layer. The cap layer may include a graphene-metal composite including graphene and a metal mixed with each other. The cap layer may be on the conductive line.

In some embodiments, the graphene-metal composite may include one of: metal particles dispersed in the graphene; graphene particles dispersed in the metal; or a carbon content profile in which a carbon content gradually decreases in a direction from the graphene to the metal.

In some embodiments, the cap layer may be in the trench.

In some embodiments, the conductive line may be between the cap layer and the dielectric layer.

In some embodiments, the cap layer may directly contact a surface of the conductive line.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view illustrating an interconnect structure according to an example embodiment;

FIGS. 2A to 2D are views illustrating a method of manufacturing an interconnect structure according to an example embodiment;

FIG. 3 is a graph illustrating experimental results of measuring variations in the resistance of a conductive line for different materials of cap layers.

FIG. 4 is a cross-sectional view illustrating an interconnect structure according to another example embodiment;

FIG. 5 is a cross-sectional view illustrating an interconnect structure according to another example embodiment;

FIG. 6 is a cross-sectional view illustrating an interconnect structure according to another example embodiment;

FIG. 7 is a cross-sectional view illustrating an interconnect structure according to another example embodiment;

FIG. 8 is a cross-sectional view illustrating an interconnect structure according to another example embodiment;

FIG. 9 is a cross-sectional view illustrating an interconnect structure according to another example embodiment;

FIG. 10 is a cross-sectional view illustrating an interconnect structure according to another example embodiment;

FIG. 11 is a cross-sectional view illustrating an interconnect structure according to another example embodiment; and

FIGS. 12A to 12G are cross-sectional views illustrating electronic devices according to some example embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

Hereinafter, example embodiments will be described with reference to the accompanying drawings. In the drawings, like reference numerals refer to like elements, and the sizes of elements may be exaggerated for clarity of illustration. The embodiments described herein are for illustrative purposes only, and various modifications may be made therein.

In the following description, when an element is referred to as being “above” or “on” another element, it may be directly on an upper, lower, left, or right side of the other element while making contact with the other element or one or more intervening elements may be present such that the element may be above an upper, lower, left, or right side of the other element without making direct contact with the other element.

The terms of a singular form may include plural forms unless otherwise mentioned. It will be further understood that the terms “comprises” and/or “comprising” used herein specify the presence of stated features or elements, but do not preclude the presence or addition of one or more other features or elements.

An element referred to with the definite article or a demonstrative pronoun may be construed as the element or the elements even though it has a singular form. Operations of a method may be performed in an appropriate order unless explicitly described in terms of order or described to the contrary, and are not limited to the stated order thereof.

In the present disclosure, terms such as “unit” or “module” may be used to denote a unit that has at least one function or operation and is implemented with hardware, software, or a combination of hardware and software.

Furthermore, line connections or connection members between elements depicted in the drawings represent functional connections and/or physical or circuit connections by way of example, and in actual applications, they may be replaced or embodied with various additional functional connections, physical connections, or circuit connections.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Examples or example terms are just used herein to describe technical ideas and should not be considered for purposes of limitation unless defined by the claims.

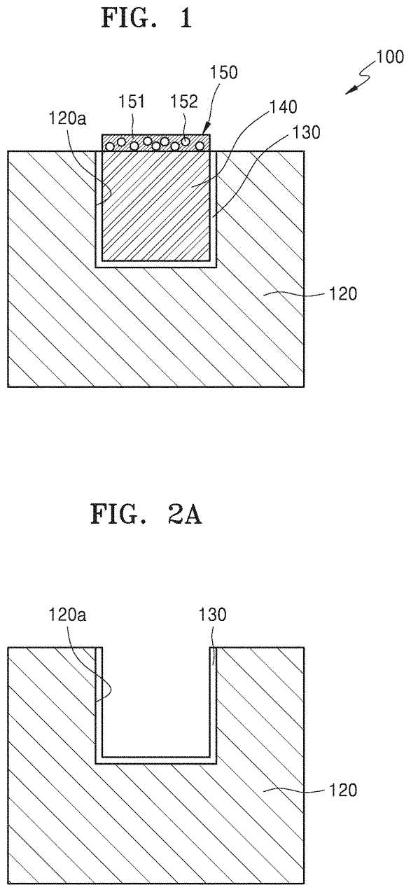

FIG. 1 is a cross-sectional view illustrating an interconnect structure 100 according to an example embodiment.

Referring to FIG. 1, the interconnect structure 100 may include a dielectric layer 120, a conductive line 140, and a cap layer 150. The interconnect structure 100 may be provided on a substrate (not shown) to form an electronic device. Examples of the electronic device may include a dynamic random-access memory (DRAM) device, a logic device, or the like, and in this case, the interconnect structure may be applied to a back end of line (BEOL) structure of the DRAM device, the logic device, or the like. However, this is merely an example.

The substrate may be a semiconductor substrate. For example, the substrate may include a Group IV semiconductor material, a Group III/V semiconductor compound, or a Group II/VI semiconductor compound. For example, the substrate may include Si, Ge, SiC, SiGe, SiGeC, a Ge alloy, GaAs, InAs, InP, or the like. However, this is merely an example, and the substrate may include various semiconductor materials other than the listed materials.

Examples of the substrate may include a silicon-on-insulator (SOI) substrate and a silicon germanium-on-insulator (SGOT) substrate. In addition, the substrate may include a non-doped semiconductor material or a doped semiconductor material.

The substrate may include at least one semiconductor device (not shown). The semiconductor device may include, for example, at least one selected from the group consisting of a transistor, a capacitor, a diode, and a resistor. However, embodiments are not limited thereto.

The dielectric layer 120 is formed on the substrate. The dielectric layer 120 may have a single-layer structure or a multi-layer structure in which different materials are stacked. The dielectric layer 120 may include a dielectric material used in a general semiconductor manufacturing process. For example, the dielectric layer 120 may include a dielectric material having a dielectric constant of about 3.6 or less. For example, the dielectric layer 120 may include a silicon oxide, a nitride, silicon nitride, silicon carbide, a silicate, or the like. However, this is merely an example, and the dielectric layer 120 may include various dielectric materials other than the listed materials. In addition, the dielectric layer 120 may include an organic dielectric material.

A trench 120a may be formed in the dielectric layer 120 to a desired and/or alternatively predetermined depth. The conductive line 140 may fill the inside of the trench 120a. The conductive line 140 may include one selected from the group consisting of a metal, a metal alloy, and a combination thereof. Here, the metal may include, for example, at least one selected from the group consisting of Cu, Ru, Al, Co, W, Mo, Ti, Ta, Ni, Pt, Cr, Rh, Ir, Pd, and Os. However, embodiments are not limited thereto, and the conductive line 140 may include various other metals.

The cap layer 150 may be provided on an upper surface of the conductive line 140 which is filled in the trench 120a. The cap layer 150 may cover an exposed surface of the conductive line 140, that is, the upper surface of the conductive line 140. The cap layer 150 may reduce the resistance of the conductive line 140 and improve the electromigration resistance of the conductive line 140, such that the interconnect structure 100 may be more reliably used.

The cap layer 150 may include a graphene-metal composite in which graphene and a metal are mixed with each other. Here, the graphene of the graphene-metal composite may include intrinsic graphene or nanocrystalline graphene.

The intrinsic graphene may be crystalline graphene and may include crystals larger than about 100 nm. In addition, the nanocrystalline graphene may include crystals, which are smaller than the crystals of the intrinsic graphene. For example, the nanocrystalline graphene may include crystals having a size of about 0.5 nm to about 100 nm.

When measured by X-ray photoelectron spectroscopy (XPS) analysis, the ratio of carbon having an sp² bonding structure to the total carbon in the intrinsic graphene may be about 100%. The intrinsic graphene may contain substantially no hydrogen. The density of the intrinsic graphene may be, for example, about 2.1 g/cc.

For example, the ratio of carbon having an sp² bonding structure to the total carbon in the nanocrystalline graphene may be about 50% to about 99%. In addition, the nanocrystalline graphene may include hydrogen in an amount of, for example, about 1 at% (atomic percent) to about 20 at%. In addition, the density of the nanocrystalline graphene may be, for example, about 1.6 g/cc to about 2.1 g/cc.

For example, the metal of the graphene-metal composite may include at least one selected from the group consisting of Ru, Co, Ti, Ta, Al, Rh, Ir, and Pt. However, embodiments are not limited thereto. The content of the metal in the graphene-metal composite may be about 1 at % to about 80 at %. However, embodiments are not limited thereto.

In the current embodiment, the cap layer 150 may include a graphene-metal composite, which includes graphene 151 and metal particles 152 dispersed in the graphene 151. Here, the metal particles 152 may have a nanoscale size, but is not limited thereto. The cap layer 150 may have a thickness of about 3 nm or less. However, embodiments are not limited thereto.

A barrier layer 130 may be provided on inner walls of the trench 120a. Here, the barrier layer 130 may be provided between the dielectric layer 120 and the conductive line 140 to cover lateral and lower surfaces of the conductive line 140. The barrier layer 130 may have a function of limiting and/or preventing diffusion of a material of the conductive line 140. In addition, the barrier layer 130 may additionally function as an adhesive layer between the dielectric layer 120 and the conductive line 140.

The barrier layer 130 may include a single-layer structure or a multi-layer structure in which a plurality of layers of different materials are stacked. The barrier layer 130 may include, for example, a metal, a metal alloy, a metal nitride, or the like. For example, the barrier layer 130 may include Ta, Ti, Ru, RuTa, IrTa, W, TaN, TiN, RuN, IrTaN, TiSiN, Co, Mn, MnO, WN, or the like. However, these materials are examples, and the barrier layer 130 may include various materials other than the listed materials. For example, the barrier layer 130 may include the aforementioned graphene (intrinsic graphene or nanocrystalline graphene). A liner layer (not shown) may be further provided between the conductive line 140 and the barrier layer 130 for improving adhesion between the conductive line 140 and the barrier layer 130.

In the interconnect structure 100 of the current embodiment, the cap layer 150 includes a graphene-metal composite in which graphene and a metal are mixed with each other, thereby reducing the resistance of the conductive line 140 and improving the electromigration resistance of the conductive line 140 as described below. Thus, the interconnect structure 100 may be more reliably used.

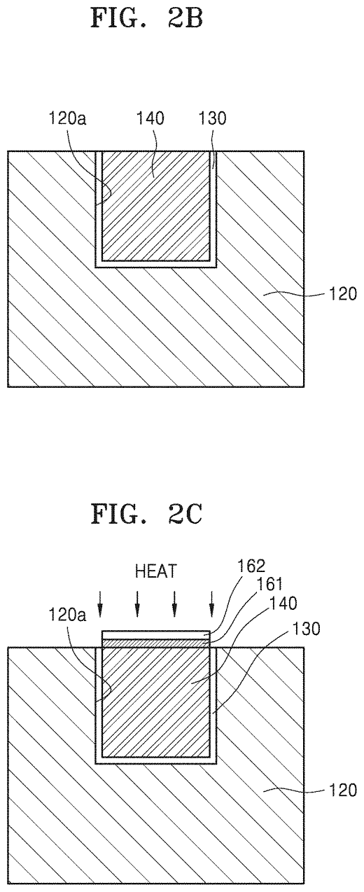

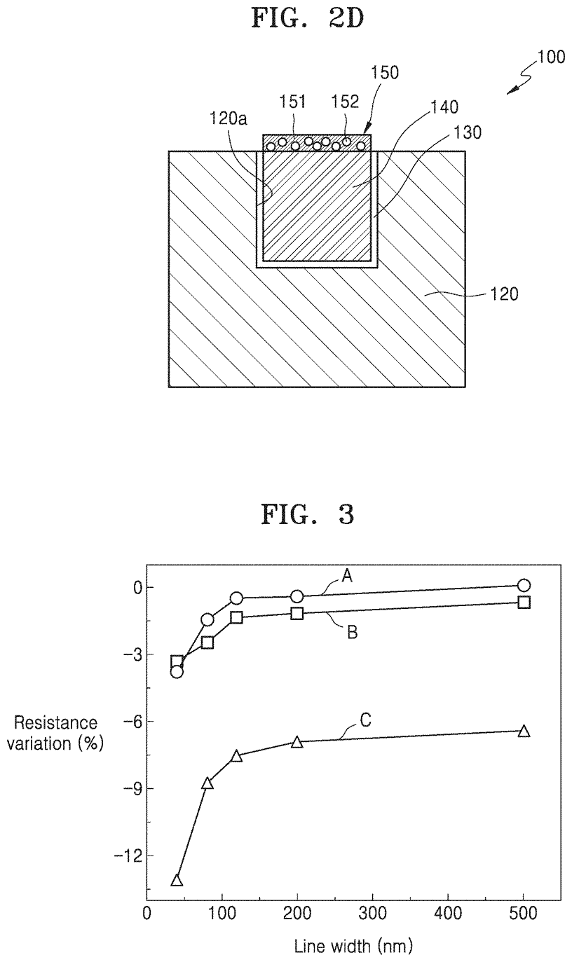

FIGS. 2A to 2D are views illustrating a method of manufacturing an interconnect structure 100 according to an example embodiment.

Referring to FIG. 2A, first, a dielectric layer 120 is formed on a substrate (not shown). The dielectric layer 120 may be formed on the substrate through a deposition process used in a general semiconductor manufacturing process, such as a chemical vapor deposition (CVD) process, a plasma enhanced chemical vapor deposition (PECVD) process, or a spin coating process.

The dielectric layer 120 may include, for example, a dielectric material having a dielectric constant of about 3.6 or less. For example, the dielectric layer 120 may include any one of silicon oxide, a nitride, silicon nitride, silicon carbide, a silicate, or the like. However, this is merely an example. The dielectric layer 120 may have a single-layer structure or a multi-layer structure in which different materials are stacked.

Next, a trench 120a may be formed in the dielectric layer 120 to a given depth. The trench 120a may be formed through, for example, a photolithography process and an etching process.

Next, a barrier layer 130 may be formed on inner walls of the trench 120a. Here, the barrier layer 130 may be formed through a deposition process used in a general semiconductor manufacturing process. The barrier layer 130 may include, for example, a metal, a metal alloy, a metal nitride, graphene, or the like. However, embodiments are not limited thereto. The barrier layer 130 may include a single-layer structure or a multi-layer structure in which a plurality of layers are stacked.

Referring to FIG. 2B, a conductive line 140 may be formed on the barrier layer 130. Here, the conductive line 140 may fill the inside of the trench 120a. For example, the conductive line 140 may be formed by CVD, PECVD, physical vapor deposition (PVD), electroplating, chemical solution deposition, electroless plating, or the like. In addition, when the conductive line 140 is formed by electroplating, a plating seed layer (not shown) for promoting electroplating may be formed on surfaces of the barrier layer 130 before forming the conductive line 140. For example, the plating seed layer may include Cu, a Cu alloy, Ir, an Ir alloy, Ru, an Ru alloy, or the like. However, this is merely an example.

The conductive line 140 may include one of a metal, a metal alloy, or a combination thereof. Here, the metal may include, for example, at least one selected from the group consisting of Cu, Ru, Al, Co, W, Mo, Ti, Ta, Ni, Pt, Cr, Rh, Ir, Pd, and Os. However, embodiments are not limited thereto. Then, upper surfaces of the dielectric layer 120, the barrier layer 130, and the conductive line 140 may be processed through a planarization process. Here, the planarization process may include, for example, a chemical mechanical polishing (CMP) process, a grinding process, or the like, but is not limited thereto.

Referring to FIG. 2C, a graphene layer 161 and a metal layer 162 may be sequentially deposited on the upper surface of the conductive line 140. The graphene layer 161 may be formed on the upper surface of the conductive line 140 by, for example, CVD. Here, the graphene layer 161 may include intrinsic graphene or nanocrystalline graphene. As described above, the intrinsic graphene may include crystals larger than about 100 nm, and the nanocrystalline graphene may include crystals having a size of about 0.5 nm to about 100 nm.

The metal layer 162 may be deposited on an upper surface of the graphene layer 161. The metal layer 162 may include, for example, at least one selected from the group consisting of Ru, Co, Ti, Ta, Al, Rh, Ir, and Pt. However, embodiments are not limited thereto.

Then, when a heat treatment process is performed on the structure shown in FIG. 2C, carbon atoms of the graphene layer 161 may move into the metal layer 162 because of high carbon solid solubility of the metal layer 162,

That is, as shown in FIG. 2D, a cap layer 150 including a graphene-metal composite may be formed on the upper surface of the conductive line 140. Here, the cap layer 150 may include a graphene-metal composite, which includes graphene 151 and metal particles 152 dispersed in the graphene 151. The cap layer 150 may be formed to a thickness of about 3 nm or less, but is not limited thereto. The content of a metal in the graphene-metal composite of the cap layer 150 may be about 1 at % to about 80 at %. However, embodiments are not limited thereto.

FIG. 2D shows an example in which the graphene-metal composite of the cap layer 150 includes the graphene 151 and the metal particles 152 dispersed in the graphene 151. However, as described later, according to the conditions or type of the heat treatment process, the cap layer 150 may include a graphene-metal composite including a metal and graphene particles dispersed in the metal, or a graphene-metal composite having a carbon content profile in which the content of carbon gradually decreases in a direction from graphene to a metal.

In the above, the graphene-metal composite is formed by sequentially depositing the graphene layer 161 and the metal layer 162 on the upper surface of the conductive line 140 and then performing the heat treatment process thereon. However, this is merely an example, and in another example, a graphene precursor and a metal precursor may be used together in a CVD process to form a graphene-metal composite on the upper surface of the conductive line 140.

FIG. 3 is a graph illustrating results of an experiment in which variations in the resistance of a Cu conductive line were measured for different materials of cap layers. In FIG. 3, “A” refers to a case in which a cap layer is not provided on an upper surface of the Cu conductive line. In addition, “B” refers to a case in which a Co cap layer is formed on the upper surface of the Cu conductive line, and “C” refers to a case in which a graphene cap layer is formed on the upper surface of the Cu conductive line.

Referring to FIG. 3, the case “B” in which the Co cap layer is formed on the upper surface of the Cu conductive line does not have a resistance reducing effect, but the case “C” in which the graphene cap layer is formed on the upper surface of the Cu conductive line has a considerable resistance reducing effect. However, when a cap layer includes only graphene, the effect of improving reliability by limiting and/or preventing electromigration is limited because of issues related to adhesion between the cap layer and a material (for example, SiCN or the like) deposited on the cap layer.

In the current embodiment, the cap layer 150 formed on the conductive line 140 includes a graphene-metal composite in which graphene having a resistance reducing effect and a metal having a reliability improving effect are mixed with each other, thereby improving reliability by reducing the resistance of the conductive line 140 and improving the electromigration resistance of the second metal layer 140.

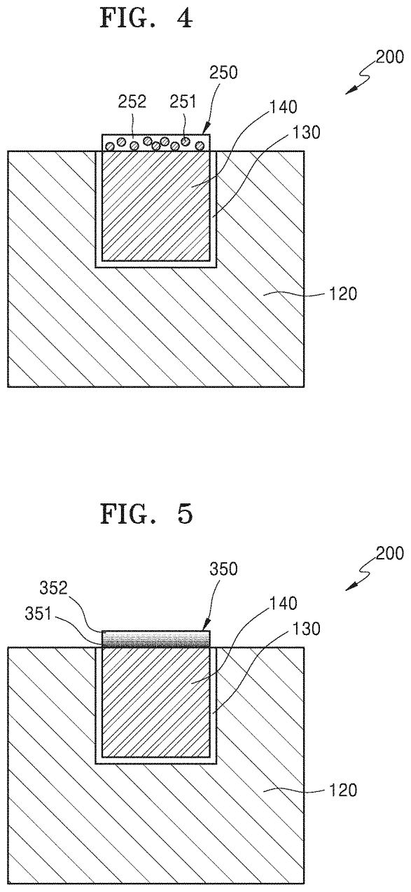

FIG. 4 is a cross-sectional view illustrating an interconnect structure 200 according to another example embodiment. Hereinafter, differences from the above-described embodiments will be mainly described.

Referring to FIG. 4, the interconnect structure 200 may include: a dielectric layer 120 in which a trench 120a is formed; a barrier layer 130 provided on inner walls of the trench 120a; a conductive line 140 provided inside the barrier layer 130 and filling the inside of the trench 120a; and a cap layer 250 provided on an upper surface of the conductive line 140.

The cap layer 250 may include a graphene-metal composite. For example, the cap layer 250 may include a metal 252 and graphene particles 251 dispersed in the metal 252. The cap layer 250 may have a thickness of about 3 nm or less, but is not limited thereto. The metal content of the graphene-metal composite of the cap layer 250 may be about 1 at % to about 80 at %.

FIG. 5 is a cross-sectional view illustrating an interconnect structure 300 according to another example embodiment.

Referring to FIG. 5, the interconnect structure 300 may include a dielectric layer 120 in which a trench 120a is formed, a barrier layer 130 provided on inner walls of the trench 120a, a conductive line 140 provided on the barrier layer 130 and filling the inside of the trench 120a, and a cap layer 350 provided on an upper surface of the conductive line 140.

The cap layer 350 may include a graphene-metal composite. For example, the cap layer 350 may include a graphene-metal composite having a carbon content profile in which the content of carbon gradually decreases in a direction from graphene 351 to a metal 352. The graphene 351 may be formed in a lower portion of the cap layer 350, and the metal 352 may be formed in an upper portion of the cap layer 350. In addition, the content of carbon between the graphene 351 and the metal 352 may be adjusted such that the content of carbon may gradually decrease in a direction from the graphene 351 to the metal 352.

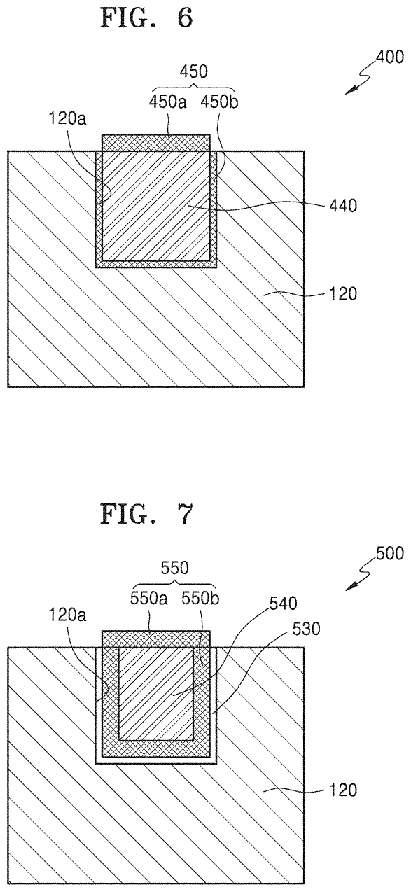

FIG. 6 is a cross-sectional view illustrating an interconnect structure 400 according to another example embodiment.

Referring to FIG. 6, the interconnect structure 400 may include a dielectric layer 120 in which a trench 102a is formed, a conductive line 440, and a cap layer 450. Here, the cap layer 450 may include a first cap layer 450a and a second cap layer 450b. Because the dielectric layer 120 and the conductive line 440 are the same as those described above, descriptions thereof will not be presented here.

The first cap layer 450a may cover an upper surface of the conductive line 440. Here, the first cap layer 450a may include a graphene-metal composite in which graphene and a metal are mixed with each other. The first cap layer 450a may have a thickness of about 3 nm or less, but is not limited thereto.

The graphene of the graphene-metal composite may include intrinsic graphene or nanocrystalline graphene. In the intrinsic graphene, the ratio of carbon having an sp² bonding structure to the total carbon may be substantially 100%. The intrinsic graphene may include substantially no hydrogen. The density of the intrinsic graphene may be, for example, about 2.1 g/cc. Furthermore, in the nanocrystalline graphene, the ratio of carbon having an sp² bonding structure to the total carbon may be, for example, about 50% to about 99%. In addition, the nanocrystalline graphene may include hydrogen in an amount of, for example, about 1 at % to about 20 at %. In addition, the density of the nanocrystalline graphene may be, for example, about 1.6 g/cc to 2.1 g/cc.

The metal of the graphene-metal composite may include, for example, at least one of (or selected from the group consisting of) Ru, Co, Ti, Ta, Al, Rh, Ir, and Pt. However, embodiments are not limited thereto. The metal content of the graphene-metal. composite may be about 1 at % to 80 at %. However, embodiments are not limited thereto.

The first cap layer 450a may be one of the cap layers 150, 250, and 350 described in the embodiments above. For example, the first cap layer 450a may include a graphene-metal composite including graphene and metal particles dispersed in the graphene. Alternatively, the first cap layer 450a may include a graphene-metal composite including a metal and graphene particles dispersed in the metal. Alternatively, the first cap layer 450a may include a graphene-metal composite having a carbon content profile in which the content of carbon gradually decreases in a direction from graphene to a metal.

The second cap layer 450b may be provided on lateral surfaces and a lower surface of the conductive line 440. The second cap layer 450b may be provided inside the trench 120a to cover the lateral surfaces and the lower surface of the conductive line 440. Like the first cap layer 450a, the second cap layer 450b may include a graphene-metal composite in which graphene and a metal are mixed with each other.

In current embodiment, the first cap layer 450a is provided on the upper surface of the conductive line 440, and the second cap layer 450b is additionally provided on the lower surface and the lateral surfaces of the conductive line 440, thereby enhancing a resistance reducing effect and a reliability improving effect. The second cap layer 450b may also function as a barrier layer.

FIG. 7 is a cross-sectional view illustrating an interconnect structure 500 according to another example embodiment.

Referring to FIG. 7, the interconnect structure 500 may include a dielectric layer 120 in which a trench 120a is formed, a conductive line 540, a barrier layer 530, and a cap layer 550. Here, the cap layer 550 may include a first cap layer 550a and a second cap layer 550b.

The barrier layer 530 may be provided on inner walls of the trench 120a. The barrier layer 530 may include, for example, a metal, a metal alloy, a metal nitride, graphene, or the like. For example, the barrier layer 530 may include Ta, Ti, Ru, RuTa, IrTa, W, TaN, TiN, RuN, IrTaN, TiSiN, Co, Mn, MnO, WN, or the like. However, this is merely an example, and the barrier layer 530 may include various materials other than the listed materials.

The first cap layer 550a may be provided on an upper surface of the conductive line 540. As described above, the first cap layer 550a may include a graphene-metal composite in which graphene and a metal are mixed with each other. The first cap layer 550a may be one of the cap layers 150, 250, and 350 described in the embodiments above. The second cap layer 550b may be provided on the barrier layer 530. The second cap layer 550b may be provided between the barrier layer 530 and the conductive line 540 to cover the lateral surfaces and the lower surface of the conductive line 540. Like the first cap layer 550a, the second cap layer 550b may include a graphene-metal composite in which graphene and a metal are mixed with each other.

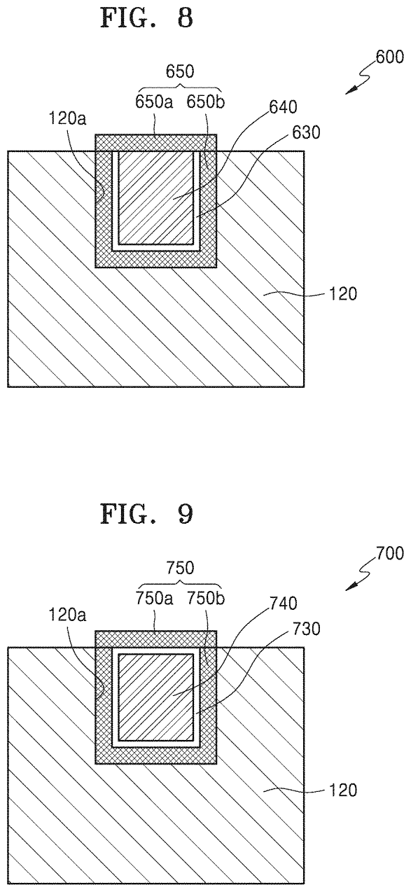

FIG. 8 is a cross-sectional view illustrating an interconnect structure 600 according to another example embodiment.

Referring to FIG. 8, the interconnect structure 600 may include a dielectric layer 120 in which a trench 120a is formed, a conductive line 640, a barrier layer 630, and a cap layer 650. Here, the cap layer 650 may include a first cap layer 650a and a second cap layer 650b.

The barrier layer 630 may be provided inside the trench 120a to cover lateral surfaces and a lower surface of the conductive line 640. The barrier layer 630 may include, for example, a metal, a metal alloy, a metal nitride, graphene, or the like.

The first cap layer 650a may be provided on an upper surface of the conductive line 640 and an upper surface of the barrier layer 630. As described above, the first cap layer 650a may include a graphene-metal composite in which graphene and a metal are mixed with each other. The first cap layer 650a may be one of the cap layers 150, 250, and 350 described in the embodiments above. The second cap layer 650b may be provided on inner walls of the trench 120a. The second cap layer 650b may be provided between the dielectric layer 120 and the barrier layer 630 to cover lateral surfaces and a lower surface of the barrier layer 630. Like the first cap layer 650a, the second cap layer 650b may include a graphene-metal composite in which graphene and a metal are mixed with each other.

FIG. 9 is a cross-sectional view illustrating an interconnect structure 700 according to another example embodiment.

Referring to FIG. 9, the interconnect structure 700 may include a dielectric layer 120 in which a trench 120a is formed, a conductive line 740, a barrier layer 730, and a cap layer 750. Here, the cap layer 750 may include a first cap layer 750a and a second cap layer 750b. The barrier layer 730 may be provided inside the trench 120a to cover upper, lateral, and lower surfaces of the conductive line 740.

The first cap layer 750a may cover an upper surface of the barrier layer 730. The first cap layer 750a may include a graphene-metal composite in which graphene and a metal are mixed with each other. The first cap layer 750a may be one of the cap layers 150, 250, and 350 described in the embodiments above. The second cap layer 750b may be provided on inner walls of the trench 120a. The second cap layer 750b may be provided between the dielectric layer 120 and the barrier layer 730 to cover lateral surfaces and a lower surface of the barrier layer 730. Like the first cap layer 750a, the second cap layer 750b may include a graphene-metal composite in which graphene and a metal are mixed with each other.

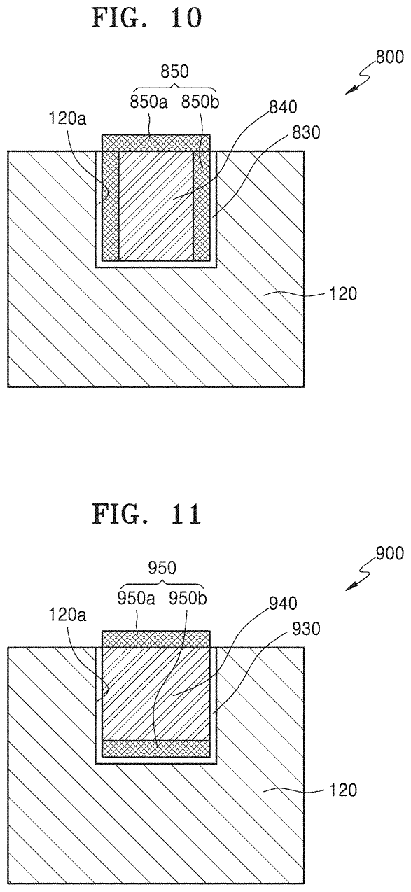

FIG. 10 is a cross-sectional view illustrating an interconnect structure 800 according to another example embodiment.

Referring to FIG. 10, the interconnect structure 800 may include a dielectric layer 120 in which a trench 120a is formed, a conductive line 840, a barrier layer 830, and a cap layer 850. Here, the cap layer 850 may include a first cap layer 850a and a second cap layer 850b. The barrier layer 830 may be provided on inner walls of the trench 120a.

The first cap layer 850a may cover an upper surface of the conductive line 840. The first cap layer 850a may include a graphene-metal composite in which graphene and a metal are mixed with each other. The second cap layer 850b may be provided on lateral surfaces of the conductive line 840. The second cap layer 850b may be provided between the barrier layer 830 and the conductive line 840 to cover the lateral surfaces of the conductive line 840. Like the first cap layer 850a, the second cap layer 850b may include a graphene-metal composite in which graphene and a metal are mixed with each other.

FIG. 11 is a cross-sectional view illustrating an interconnect structure 900 according to another example embodiment.

Referring to FIG. 11, the interconnect structure 900 may include a dielectric layer 120 in which a trench 120a is formed, a conductive line 940, a barrier layer 930, and a cap layer 950. Here, the cap layer 950 may include a first cap layer 950a and a second cap layer 950b. The barrier layer 930 may be provided on inner walls of the trench 120a.

The first cap layer 950a may cover an upper surface of the conductive line 940. The first cap layer 950a may include a graphene-metal composite in which graphene and a metal are mixed with each other. The second cap layer 950b may be provided on a lower surface of the conductive line 940. The second cap layer 950b may be provided between the barrier layer 930 and the conductive line 940 to cover the lower surface of the conductive line 940. Like the first cap layer, the second cap layer 950b may include a graphene-metal composite in which graphene and a metal are mixed with each other.

In each of the interconnect structures of the example embodiments described above, the cap layer formed on the conductive line includes a graphene-metal composite in which graphene having a resistance reducing effect and a metal having a reliability improving effect are mixed with each other, thereby improving reliability by reducing the resistance of the conductive line and improving the electromigration resistance of the conducive line. For example, the interconnect structures may be applied to BEOL structures or the like of electronic devices such as DRAM devices or logic devices.

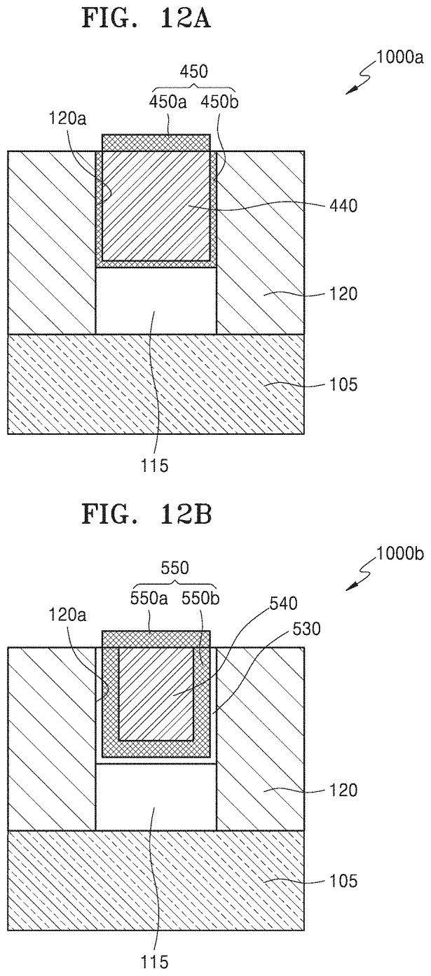

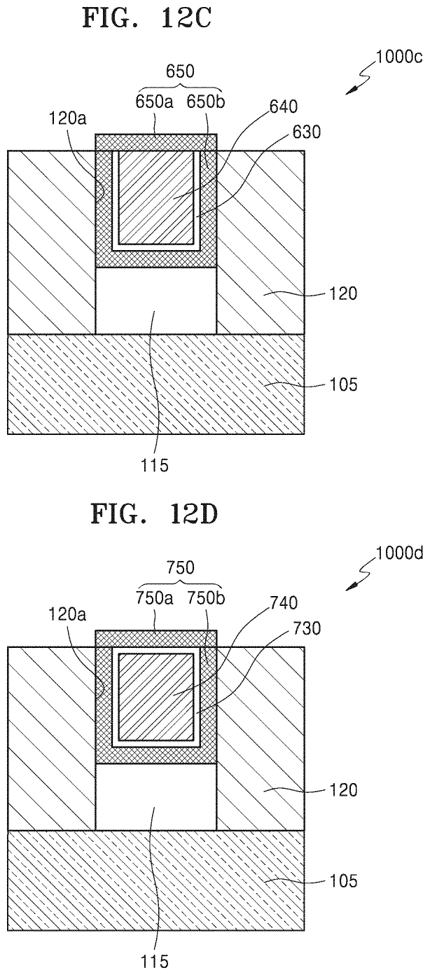

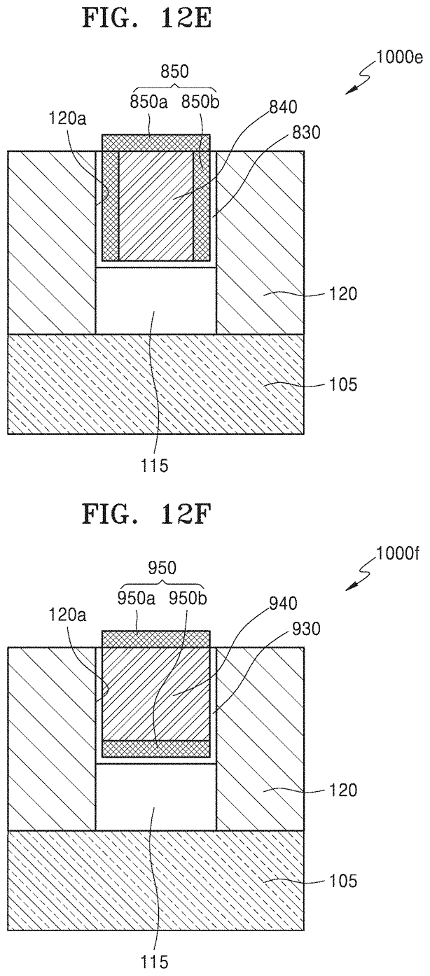

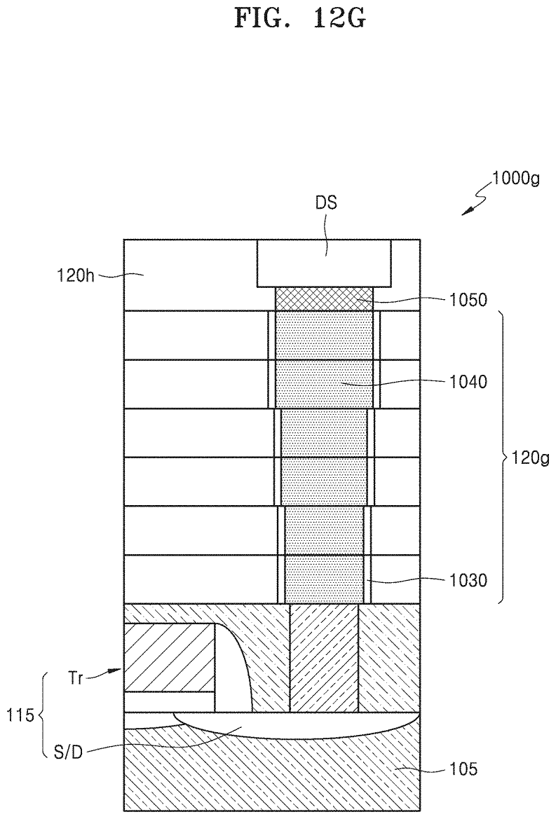

FIGS. 12A to 12G are cross-sectional views illustrating electronic devices according to some example embodiments. For brevity, differences between FIGS. 6 to 11 and FIGS. 12A to 12G mainly will be discussed.

Referring to FIGS. 12A to 12F, in some embodiments, electronic devices 1000a to 1000f may include any one of the interconnect structures 400, 500, 600, 700, 800, and 900 discussed above, with reference to FIGS. 6 to 11, respectively. The interconnect structures 400, 500, 600, 700, 800, and 900 may be formed on a device element 115 and a substrate 105. The device element 115 may be between the substrate 105 and the conductive lines 440, 540, 640, 740, 840, and 940, respectively. An upper surface of the device element 115 may contact the second cap layers 450b, 650b, 750b (see FIGS. 12A, 12C, 12D) and/or barrier layers 530, 830, 930 (see FIGS. 12B, 12E, and 12F). An upper surface of the device element 115 may directly contact the second cap layers 450b, 650b, 750b (see FIGS. 12A, 12C, 12D) or barrier layers 530, 830, 930 (see FIGS. 12B, 12E, and 12F).

The device element 115 may include an electrode or another part of a circuit structure. The circuit structure may be a capacitor, a diode, a resistor, or a wire, but is not limited thereto. In some embodiments, a liner layer (not shown) may be between the conductive lines 440, 540, 640, 740, 840, and 940 and the dielectric layer 120 and/or device element 115. The substrate 105 may include Si, Ge, SiC, SiGe, SiGeC, a Ge alloy, GaAs, InAs, InP, or the like. However, this is merely an example, and the substrate may include various semiconductor materials other than the listed materials. Examples of the substrate 105 may include a silicon-on-insulator (SOI) substrate and a silicon germanium-on-insulator (SGOT) substrate.

In addition, the substrate 105 may include a non-doped semiconductor material or a doped semiconductor material. For example, as depicted in FIG. 12G, in an electronic device 1000g according to an embodiment, a substrate 105 may include a source/drain region S/D formed by doping an impurity into a region of the substrate 105.

Referring to FIG. 12G, a device element 115 on the substrate 105 may include a transistor Tr that includes the source/drain region S/D. A dielectric layer 120g may be formed on the device element 115 and substrate 105. A conductive line 1040 may be formed in the dielectric layer 120g and may extend through the dielectric layer 120g in a vertical direction. A data storage structure DS, such as a capacitor, may be formed on the conductive line 1040. Another dielectric layer 120h may be formed on the dielectric layer 120g and surround the data storage structure DS. A cap layer 1050 may be formed on an upper surface of the conductive line 1040. The cap layer 1050 may be one of the cap layers 150, 250, and 350 described in the embodiments above. Barrier layers 1030 may be provided between the dielectric layer 120g and the conductive line 1040. Although not illustrated, the electronic device 1000g may further include a cap layer made of a graphene-metal composite between conductive line 1040 and the device element 115 and/or between the conductive line 1040 and the dielectric layer 120g.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of inventive concepts as defined by the following claims.

What is claimed is:

1. An interconnect structure comprising:
a dielectric layer comprising a trench;
a conductive line in the trench; and
a first cap layer on an upper surface of the conductive line, the first cap layer comprising a graphene-metal composite comprising graphene and a metal mixed with each other.

2. The interconnect structure of claim 1,
wherein the graphene-metal composite comprises metal particles dispersed in the graphene.

3. The interconnect structure of claim 1,
wherein the graphene-metal composite comprises graphene particles dispersed in the metal.

4. The interconnect structure of claim 1,
wherein the graphene-metal composite has a carbon content profile in which a carbon content gradually decreases in a direction from the graphene to the metal.

5. The interconnect structure of claim 1,
wherein the graphene comprises intrinsic graphene or nanocrystalline graphene.

6. The interconnect structure of claim 1,
wherein the metal comprises at least one of Ru, Co, Ti, Ta, Al, Rh, Ir, and Pt.

7. The interconnect structure of claim 1,
wherein the graphene-metal composite comprises the metal in an amount of about 1 at % to about 80 at %.

8. The interconnect structure of claim 1,
wherein the first cap layer has a thickness of about 3 nm or less.

9. The interconnect structure of claim 1,
wherein the conductive line comprises a metal element, a metal alloy, or a combination thereof.

10. The interconnect structure of claim 9,
wherein the conductive line comprises at least one of Cu, Ru, Al, Co, W, Mo, Ti, Ta, Ni, Pt, Cr, Rh, Ir, Pd, and Os.

11. The interconnect structure of claim 1,
wherein the dielectric layer comprises a dielectric material having a dielectric constant of about 3.6 or less.

12. The interconnect structure of claim 1, further comprising:
a second cap layer inside the trench on a lateral surface of the conductive line and a lower surface of the conductive line,
wherein the second cap layer comprises the graphene-metal composite.

13. The interconnect structure of claim 1, further comprising:
a barrier layer on the conductive line inside the trench.

14. The interconnect structure of claim 13,
wherein the barrier layer covers a lateral surface of the conductive line and a lower surface of the conductive line.

15. The interconnect structure of claim 14,
wherein the barrier layer covers the upper surface of the conductive line.

16. The interconnect structure of claim 13,
wherein the barrier layer comprises a metal element, a metal alloy, a metal nitride, or graphene.

17. The interconnect structure of claim 13, further comprising:
a second cap layer provided on a lateral surface of the barrier layer and a lower surface of the barrier layer, wherein
the second cap layer comprises the graphene-metal composite.

18. The interconnect structure of claim 13, further comprising:
a second cap layer on a lateral surface of the barrier layer, wherein
the second cap layer comprises the graphene-metal composite.

19. The interconnect structure of claim 13, further comprising:
a second cap layer on a lower surface of the barrier layer, wherein the second cap layer comprises the graphene-metal composite.

20. An electronic device comprising:
the interconnect structure of claim 1.

21. An interconnect structure comprising:
a dielectric layer comprising a trench;
a conductive line in the trench; and
a cap layer on the dielectric layer,
the cap layer comprising a graphene-metal composite comprising graphene and a metal mixed with each other, and
the cap layer on the conductive line.

22. The interconnect structure of claim 21, wherein the graphene-metal composite comprises one of:
metal particles dispersed in the graphene;
graphene particles dispersed in the metal; or
a carbon content profile in which a carbon content gradually decreases in a direction from the graphene to the metal.

23. The interconnect structure of claim 21, wherein
the cap layer is in the trench.

24. The interconnect structure of claim 21, wherein
the conductive line is between the cap layer and the dielectric layer.

25. The interconnect structure of claim 21,
the cap layer directly contacts a surface of the conductive line.
